(19) United States
(12) Patent Application Publication
(10) Pub. No.: US 2011/0045205 A1
(43) Pub. Date: Feb. 24, 2011

(54) Device and Process for Very High-Frequency Plasma-Assisted CVD under Atmospheric Pressure, and Applications Thereof

(75) Inventors: Jean-Christophe Rostaing, Versailles (FR); Daniel Guerin, Chelles (FR); Frederic Noel, Antony (FR); Helene Daniel, Le Chesnay (FR)

Correspondence Address: American Air Liquide, Inc.;Intellectual Property Dept., 2700 Post Oak Boulevard, Suite 1800, Houston, TX, 77056, US

(73) Assignee: L'Air Liquide Societe Anonyme Pour L'Etude Et L'Exploitation Des Procedes Georges Claude, Paris (FR)

(21) Appl. No.: 12/679,239

(22) PCT Filed: Sep. 16, 2008
(86) PCT No.: PCT/FR2008/051660

§ 371 Date: Nov. 1, 2010

(30) Foreign Application Priority Data
Sep. 20, 2007 (FR) 0757720

(51) Int. Cl. C23C 16/511; C23C 16/50; C23C 16/42; C23C 16/00; C23C 16/40

(52) U.S. Cl. 427/576; 427/569; 427/578; 118/723 R; 118/723 AN

(57) ABSTRACT

The invention relates to a method for CVD on a substrate under atmospheric pressure, characterized in that it is assisted by a very-high-frequency plasma generated by a field applicator with an elongated conductor of the micro-ribbon or hollow conducting line type. The invention also relates to the use thereof for applying an electrically conductive inorganic layer on elements of vehicle bodywork, particularly the bumpers.

The invention relates to an atmospheric-pressure very high-frequency (including microwave) plasma-enhanced CVD deposition process, also to a device for implementing it and to applications of said process.

There are many potential applications for thin-film functional coatings on glass, metal or polymer substrates. These thin films are advantageously produced by PECVD (plasma-enhanced chemical vapor deposition) technology also commonly called plasma-CVD. The principle of this technology is to excite chemical vapor in a plasma produced by an electrical discharge, said vapor being in contact with a substrate. The effect of the plasma is to create highly reactive unstable precursors in the gas phase that have the property of condensing on and reacting with the surface of the substrate in order to provide new atoms that progressively constitute a thin surface film of material.

By choosing the nature and the proportions of the gaseous chemical precursors, it is possible to produce materials of various compositions that can be adjusted with great flexibility (for example amorphous silicon oxycarbonitride alloys SiOₓN_{y}C_{z}). It is also possible to produce gradients of properties through the thickness by continuously controlling the characteristics of the plasma phase, something which proved to be impossible with the older methods of PVD (physical vapor deposition) such as sputtering in which the raw material of the films is provided by solid sources. In addition, PECVD is potentially better suited to uniform deposition of material on objects of three-dimensional shape, since the transport of the chemical species is less directional than that of physical species (evaporated or sputtered atoms) and may be controlled by varying the hydrodynamics and the diffusion in the gas phase.

Originally, plasma-CVD technology was developed for the formation of thin films of materials constituting microelectronic circuits, LCD flat screens and solar cells. These applications require the use of ultraclean reactors with gases of very high purity and a substrate temperature of at least about 200° C.

For new applications of coatings providing one or more functionalities of the following types: abrasion resistance, chemical barrier, thermal barrier, corrosion resistance, optical filtering, adhesion primer, UV resistance, etc., the demands on the materials, processes and equipment are very different.

A material considered to be of high quality for these applications must above all have a dense structure with on average good connectivity of the atomic lattice, minimal porosity on a nanoscale, and absence of heterogeneous column or granular structures on a micron scale. On the other hand, localized electrically active defects are not in general of major importance. Moreover, these new thin-film functional coatings are aimed at products with a very low added value per unit area compared, for example, with a microcircuit wafer or a display screen. It is therefore absolutely necessary to minimize the depreciation and operating costs of the deposition machines per m² treated. The deposition rate therefore must be as high as possible. Most of the industrial products for which these new applications of functional coatings are applied, especially products made of polymers, steels and aluminum alloys in thin sheet form, cannot withstand a temperature more than a few tens of degrees above room temperature. Flat glass may however withstand reheating, but the treatment involved at a later stage, after hot fabrication, namely the reheating treatment, would be an undesirable waste of energy for manufacturers. The objects to be coated are generally larger than a silicon wafer, a solar cell or an LCD screen, and may be of three-dimensional shape. It may also be necessary to treat continuously running thin substrates.

To meet these various application-specific requirements, reduced-pressure PECVD solutions have been gradually developed and are presently available on a laboratory or industrial pilot scale. They generally combine:
high-density, microwave, inductive or transferred-arc plasma sources that are capable of delivering a high density of excited free electrons, making it possible to generate, by inelastic collisions, a large quantity of deposition precursors and thereby obtain the highest growth rates while minimizing the treatment times;
a means supplying the substrates with a large and controllable amount of nonthermal energy, in the form of internal physical excitation of species or ion bombardment; and
large PECVD reactors of complex engineering in order to create, transport and deliver a uniform high flux of chemical and physical nonthermal active species at all points on the surface of the substrate.
   This means distributed plasma sources, thoroughly investigated chemical gas injection modes and distributed pumping. It is often advantageous to work at minimal pressures, of the order of a few 0.1 Pa, so as to obtain a long mean free path and to minimize the influence of the hydrodynamics.

Complex arrangements that are tricky to implement are necessary in order to envision the possibility of coating uniformly on large areas. The reason they for example refer to the developments that have been necessary in recent years in the concept of distributed electron cyclotron resonance by the company Metal Process SARL. The delocalized gas injection devices rely on delicate mechanical execution with a large number of very small-diameter holes. Distributed turbomolecular pumping is also expensive (several small pumps are more expensive than one large pump of equivalent combined capacity).

This type of technology remains reserved to the formation of coatings having quite complex functionalities and of sufficient added value, namely: optical filters, multiple (wear, external aging, chemical barrier) protective coatings, innovative nanomaterials, etc.

To create simpler surface functionalities using a plasma process, aimed at commonplace products of little added value, which may be of large size and awkward shape, manufactured in very large quantity, there is a real need for a PECVD deposition technology which is simple, inexpensive and easy to implement at atmospheric pressure.

Moreover, the constraints associated with the infrastructures for maintaining a vacuum are very considerable. In addition to the operating costs (in terms of energy, maintenance, spare parts, consumables, skilled operators), a large-size vacuum installation requires specific know-how and infrastructures for operating it 24 hours a day in a reliable manner and with a high productivity, by controlling complex systems of sequential or continuous airlocks, loading and unloading operations forming bottlenecks, etc. Moreover, in the event of a breakdown, breaking the vacuum which is necessary to carry out intervention work is time-consuming, incompatible with very critical tight-flow continuous production lines.

However, at atmospheric pressure, compared with the case in which the gas in which it is sought to sustain a nonthermal plasma is in a rarefied state, the elementary physical and chemical processes are modified, imposing larger constraints on the development of plasma-CVD technologies and restricting the possible applications.

Firstly, the very existence of nonthermal discharge regimes at atmospheric pressure represents a singular physical situation, to obtain which requires very particular arrangements of devices and operating methods. This is because, when the particle density in the gas increases, the collisions also become much more frequent and tend to establish local thermodynamic equilibrium, that is to say the transition to an arc regime which, unless special precautions are taken, can cause degradation or destruction of the device.

Moreover, because of the much more frequent interactions between particles, all the gradients are much more pronounced in an atmospheric-pressure plasma device or PECVD reactor. The electrons and ions, and also the chemical and physical active species involved in the plasma process, disappear over very much shorter characteristic lengths than in the case of a vacuum plasma. This means it becomes even more difficult to generate a plasma and distribute the active species uniformly on geometries other than very elementary ones. In particular, there is no possibility of producing an atmospheric-pressure plasma deposition reactor capable of treating a substrate of three-dimensional shape which would be kept fixed relative to one or more plasma generators. It is often even impossible to place such a substrate inside the plasma zone because of the geometric constraints.

The strong interactions between particles in the gas phase have another consequence on the quality of the materials deposited: the radical chemical species constituting the raw material for the coating will have a substantial tendency to react prematurely with one another before even reaching the surface of the film. This may result in nucleation in a homogeneous phase and in the irreversible generation of completely undesirable solid particles. To a lesser degree, the radicals will aggregate into clusters of bound atoms of larger size which, just after their arrival on the surface, will be more difficult to rearrange, by supplying nonthermal energy, than atoms that condense individually. Now, again because of the fact that the interactions between particles are more frequent in the gas phase, the species carrying this nonthermal energy lose their internal excitation more easily than in a rarefied gas before reaching the surface. This deficiency cannot be compensated for by applying an ion bombardment to the substrate as it is impossible, at atmospheric pressure, for the substrate to be substantially biased relative to the plasma. It is therefore particularly problematic using atmospheric PECVD to obtain films of quality comparable to those obtained by reduced-pressure PECVD.

Another condition for being able to use a nonthermal atmospheric discharge to deposit PECVD coatings is that the energetic electrons, which will then be the source of generating the depositing species, are created by ionization processes taking place homogeneously within the volume and continuously over time, as is the case in a vacuum plasma. Failing this, the deposited material would have an irregular and heterogeneous structure and be of unsuitable quality.

Among nonthermal atmospheric discharges, the most common type is dielectric barrier discharge (DBD) sustained between two electrodes supplied with low-frequency AC voltage and the surfaces of the electrodes are coated with a dielectric. This dielectric prevents the transition to the arc regime by limiting the discharge current. However, this arrangement does not in general enable a homogeneous discharge to be obtained. As soon as sufficient power is applied in order to achieve the ignition or “breakdown” of the discharge (i.e. to achieve a regime in which the ionization compensates for the loss of charged particles), it is found that the ionization intensifies and propagates very rapidly along paths perpendicular to the electrodes, giving a large number of plasma streamers separated by dark spaces where there are no charges and consequently where no depositing active species can be created. The presence of the dielectric “aborts” each streamer before it is indefinitely amplified, passing into the arc regime, but the discharge is not correspondingly homogeneous and cannot be used for PECVD.

However, a homogeneous dielectric barrier discharge has been successfully obtained in recent years: an atmospheric discharge in glow regime in rare gases or in Townsend regime in nitrogen. To ignite a sustained discharge, while still remaining in a “soft” ionization regime taking place in a distributed manner throughout the volume between the electrodes, it is necessary to promote the ionization mechanisms that involve, not direct inelastic electron collisions (which would result in the streamer regime), but energy transfer between species other than the electrons carrying the internal excitation (i.e. species in one of their quantum energy levels above the ground state), especially metastable atoms and molecules. Correspondingly, the amplitude and the frequency of the voltage signal, which governs the energy deposition regime in the discharge, and therefore the creation of species that will control the desired ionization regime, are adapted.

These conditions for homogeneous discharging to take place are however tenuous and conflicting. For example, it may be necessary to add to the plasma gas a gas which, when excited, will give a particular metastable species necessary for controlling the ionization regime, but this gas may moreover be undesirable regards the process. Conversely, the addition of a chemical precursor vapor may react with an excited species involved in the homogeneous ionization process and cause it to disappear prematurely, and therefore to make the discharge return to the streamer regime. The conditions for sustaining the homogeneous regime may also be sensitive to additional constraints imposed by the PECVD process, such as the gas flow rate and the substrate heating.

Furthermore, the geometries in which these homogeneous regimes can be maintained are also limited: plane parallel electrodes may have a relatively large area, but on the other hand the gap cannot exceed a few millimeters in the case of a homogeneous Townsend discharge in nitrogen and slightly more in the case of a homogeneous glow discharge in rare gases. This excludes the treatment of substrates other than thin flat substrates. Furthermore, inherent in the physical mechanisms for sustaining the homogeneous discharge, these substrates must be made of a relatively insulating material. Introducing any conducting substrate within the discharge immediately results in the transition to inhomogeneous streamer mode.

Other homogeneous cold atmospheric discharges exist, these being essentially flux-sustained discharges in a tubular geometry of circular or parallelepipedal cross section, in the latter case optionally extended widthwise (in the so-called APPJ (atmospheric-pressure plasma jet concept, as sold by the company SurfX Technologies). The plasma is ignited between the wall of the tube and an internal counterelectrode, without the need for a dielectric barrier. As a result of using a high flow rate of virtually pure helium as plasma gas, ensuring very effective dethermalization, the discharge is stabilized and sustained away from the arc regime. However, all attempts at adding other plasma gases, especially nitrogen or argon, have made the discharge unusable for applications. Apart from the cost, the use of helium, a nonrenewable resource and often in short supply on the market, which gas may be reserved for more strategic applications, is undesirable.

Another concept exists, developed by the University of Wisconsin (see document U.S. Pat. No. 6,764,658), which consists of a plurality of coaxial dielectric barrier flow discharges juxtaposed in parallel. These tubular sources are provided in a parallelepipedal block facing which there is a substrate of extended shape. The gas flow has the effect of partially ejecting the plasma (glow zone in which charge particles exist) outwardly toward the surface of the substrate to be treated, but the decrease in these species is rapid and the treatment is carried out at the post-discharge plasma limit where the active species are both less numerous and less energetic. A high deposition rate with good film quality cannot be obtained with this system.

Finally, there are a number of “cold torch” concepts, in which the torches are supplied with high-frequency or low-frequency AC voltage, or with pulsed DC voltage, which, by appropriate arrangements, make it possible to transform a streamer with an arc character into a more diffuse and colder plasma. These torches do not require stabilization by rare gases and may for example operate in air. However, they do not allow high-density plasmas to be created nor is the production of the active species controlled very well. These torches are tools very useful for carrying out simple surface cleaning, descaling, deoxidation or activation operations. Moreover, even if nothing prevents them from being combined with the injection of deposition precursors, it would only be possible to carry out very simple polymerizations and not the deposition of thin films with very precise, controllable and reproducible specifications, and especially not at a high rate required for most industrial applications.

Homogeneous cold atmospheric discharges have electron densities that are of the same order of magnitude as vacuum-sustained radiofrequency capacitive glow discharges (i.e. 10⁸ to 10⁹ cm⁻³). The rate at which the active species are created under these conditions does not result in very high deposition rates.

In contrast, microwave atmospheric discharges have manifestly high electron densities, from 10¹² to 10¹⁵ cm⁻³ at most close to coupling of the microwaves with the plasma, and the inelastic electron collisions produce a large number of chemical and physical active species that are favorable to a high deposition rate with good film quality. It is therefore also envisioned to employ microwave atmospheric discharges for surface treatment.

There are various families of devices for generating a microwave plasma and some of these may in principle operate at atmospheric pressure. The main types of sources are for example described in “Microwave-Excited Plasmas” published by M. Moisan and J. Pelletier, chapters 4-5, Elsevier (1992): said sources being located inside microwave waveguide circuits, resonant cavities, surface wave launchers and torches. Except in the case of resonant cavities, these devices sustain plasmas within small volumes (generally inside small-diameter dielectric tubes), which basically renders them not very suitable for CVD deposition on articles of extended shape. There are also microwave field applicators of plane geometry enabling plasmas to be sustained over extended areas, for example radiating-slot waveguides, plane propagators or plane surface wave launchers.

However, this is so only in the case of vacuum plasmas. This is because at atmospheric pressure the phenomenon of microwave discharge contraction and filamentation occurs (Y. Kabouzi et al., Journal of Applied Physics 91 (3), 1008 (2002)). This inhomogeneity has a very different physical origin from that prevailing in cold atmospheric discharges and results from the inhomogeneous heating of the gas by the elastic electron collisions. This mechanism actually has a tendency to establish abrupt temperature gradients, which are associated with electron density gradients in the same sense within the plasma. In an extended volume, the plasma concentrates in very intense discrete streamers separated by spaces containing little or no charges, and therefore a negligible number of active species. Any homogeneous deposition is impossible and the substrate to be treated suffers localized thermal damage.

As an exception to this rule, two cases are known in which a uniform atmospheric microwave plasma may be obtained in an appreciable volume. The first is the Cyrannus® source from the company iPlas GmbH, which uses a resonant cavity supplied via a slotted annular waveguide. It is the high argon flux that prevents the gas from being inhomogeneously heated. However, this regime is intrinsically unstable and the transition to inhomogeneous mode may occur on normal fluctuations of the process. Even in homogeneous operation, the PECVD (silicon nitride SiN) trials have resulted in unacceptable inhomogeneities. The deposition rate does not appear to be considerable, no more than a few hundred nanometers per minute, which may be explained by the fact that the high flow rate of the carrier gas “dilutes” the injected power, correspondingly reducing the rate of creation of depositing species. The very high argon consumption is also an unfavorable economic factor.

The second example relates to the AtmoPlas™ technology from the company Dana Corporation (from now on the property of BTU International). In this concept, the plasma is homogenized on average by dispersing conducting particles in the gas that act as delocalized ignition centers and thus permanently induce microwave absorption in order to ionize the gas throughout the volume. However, the presence of these particles does not seem to be compatible with CVD deposition of a coating of well controlled composition and microstructure.

The definition of the lower limit of the corresponding frequency range usually ascribed to microwaves is not absolute. One of the legally permitted frequencies for ISM (industrial, scientific and medical) applications is 434 MHz, a frequency that some authors consider not to be covered by the term “microwave” (whereas this name is assigned to frequencies immediately above the permitted frequency of 915 MHz). We will therefore instead refer hereafter to very high frequencies to denote those lying well above 100 MHz.

The present inventors have described in the patent application filed on the same day by the Applicant a very high-frequency plasma source using an elongate conductor (of the microstrip line or hollow-conductor line type). The principle of this plasma source is based on a linear structure for propagating very high-frequency waves, formed by the hollow-conductor line or microstrip line, applied to a dielectric substrate that separates it from the plasma. The plasma is generated by the very high-frequency power absorbed during its propagation along the conductor.

More precisely, the patent application filed by the Applicant on the same day as the present application relates to a plasma generator device that comprises at least one very high-frequency (greater than 100 MHz) power source connected via an impedance matching system to an elongate conductor of small cross section compared with its length (for example on the microstrip line or hollow-conductor line type) fixed, in intimate contact over its entire lower surface, to a dielectric support, at least one means for cooling said conductor, at least one plasma gas feed close to the dielectric support on the opposite side from the side supporting the conductor. The principle of this method of generating the plasma is therefore that of propagating the electromagnetic power along the power transmission line based on the microstrip line in order to distribute this power and excite the plasma in a delocalized manner along the line. In fact, the specific existence of said line requires the presence of a ground reference which, in the prior art, takes the form of a continuous conducting metal plane.

According to advantageous embodiments of this plasma generator device, the Applicant can be credited with the idea of considering that the plasma sheet is a conductor with an intrinsic potential that may consequently serve perfectly well as a potential reference for the power transmission line. However, in order for the device to actually operate, it is necessary to add an absolute local potential reference enabling the propagation mode to be established:
the device includes a partial ground plane extending opposite that face of the dielectric on the opposite side from that supporting the conductor, the partial character of the ground plane being expressed by the fact that only a small area of the conductor line lies opposite a ground plane;
the partial ground plane is located at the origin of the conductor line, at the point where the microwaves arrive in the device;
the microwave launch zone, at the conductor line input, has a conventional structure comprising the elongate conductor, the dielectric and the partial ground plane, the ground plane being interrupted at a short distance from the conductor line input and then being replaced, as potential reference, for guided microwave propagation, by the plasma extending with the conductor over the entire remainder of the length of the conductor line; and
the microwave launch zone, at the conductor line input, has a conventional structure comprising the elongate conductor, the dielectric and the partial ground plane, the ground plane being interrupted at a short distance from the conductor line input and then being replaced by the plasma, the conductor not extending substantially beyond the boundary of the ground plane. Thus, the plasma acts both as a potential reference and as a wave propagation guide support (a mode similar to a surface wave, but here in plane geometry).

The present invention is based on the use of this type of very high-frequency plasma source with a microstrip line field applicator to produce a CVD plasma module delivering an active gas flow “curtain”, said gas being excited beforehand in the dense homogeneous plasma, said active gas curtain impinging on the surface of a substrate. On said surface, the active gas may again have the characteristics of a plasma, i.e. it may contain a non-negligible proportion of charged particles, or may essentially be a post-discharge plasma medium, in other words one containing only neutral excited and/or active species. It is the most rapid flow rates that promote the subsistence of charged species (which are those having a population that decreases the most rapidly) a certain distance from their site of creation by coupling the energy of the electromagnetic wave into the gas. This plasma device has the highest efficiency in terms of use of the electrical energy to create depositing active species. The electrical energy is not substantially converted into heat, as would be the case for example in an arc plasma, and the temperature of the gas remains low enough for the treatment of heat-sensitive substrates to be possible, by adapting the rate at which the substrate passes through the active gas jet. The plasma module may be used to deposit thin films of material on flat running substrates, or else may be mounted on a robot arm in order to carry out the same treatments by a controlled scanning movement on three-dimensional substrates.

In particular, the invention is well suited to applying an electrically conducting inorganic film on polymeric automobile body components, particularly fenders, before the paint is sprayed electrostatically thereon. This film is intended to replace conducting adhesion primer solutions applied using liquid processing and requiring a time-consuming drying operation.

In a very high-frequency plasma device using a microstrip line, according to the concept forming the basis of the present invention, when the wall of the dielectric in contact with the plasma is plane and extended and when the gas is virtually scattered, it has been found that the atmospheric-pressure plasma has a streamer structure whatever the plasma gas employed, especially argon or helium or mixtures thereof. To stabilize and homogenize the plasma, an arrangement enabling trials to be carried out, in which a lateral gas flow is established at the boundary of the intense plasma zone corresponding to coupling with the very high-frequency electromagnetic power, said plasma zone being confined in a narrow channel provided in the dielectric substrate, was adopted. The results of these trials show characteristics very suitable for developing a PECVD device.

Thus, the present invention relates to a CVD process for deposition on a substrate, which is carried out at atmospheric pressure, characterized in that it is assisted by a very high-frequency plasma produced by a field applicator using an elongate conductor of small cross section compared with its length (that the conductor is of the microstrip line type or of the hollow, for example, cylindrical, line type). The plasma source is supplied with electromagnetic power (for example at 434 MHz) by specially designed solid-state generators. These generators benefit from the power electronics technologies used in the telecommunications industry and especially for the mass production of power transistors, which ensures both security of supply and a rapid reduction in costs with the quantities ordered. Furthermore, they do not require any periodic maintenance, unlike generators based on vacuum tubes (magnetrons, etc.) which all have a limited lifetime.

As will have been understood on reading the foregoing, the term “very high-frequency” is understood according to the invention to mean frequencies above 100 MHz and especially the following “discrete” frequencies: 434 MHz, 915 MHz, 2450 MHz and 5850 MHz which are permitted by international regulations for the ISM band.

In the process according to the invention, the plasma gas is preferably argon to which is optionally added 0.1 to 5%, preferably 0.2 to 4% and even more preferably 0.5 to 2% nitrogen by volume. In argon, the sustained plasma in the geometry of the device according to the invention, remains visually homogeneous without apparent manifestation of contraction or filamentation. However, operation at atmospheric pressure in pure nitrogen is impossible: not only are sufficiently powerful microwave sources not available, but also the structure is not designed to contain the minimum power densities corresponding to sustaining an atmospheric nitrogen plasma. The use of argon is perfectly permissible from the economic standpoint for most industrial processes targeted by the invention. The possible addition of a few percent of nitrogen may help to modify energy transfer in the discharge in order to promote the formation of certain depositing radicals.

The chemical nature of the precursor will of course be chosen firstly according to the chemical elements that have to form the solid material to be deposited. However, other criteria specific to the use of the precursor in the atmospheric PECVD process will be taken into account. Some of these precursors will be “normal” gases stored in compressed form, or liquefied under a high vapor pressure at room temperature, such as for example silane, methane, acetylene, etc. However, if it is desired to extend the range of possible materials (metals and their oxides, nitrides, carbides, etc.), it is necessary in general to envisage also using liquid organometallic sources of low vapor pressure, which will be conveyed in an atmospheric-pressure carrier gas. This carrier gas may be chosen from the group comprising argon, nitrogen, helium, krypton, xenon and neon. Said carrier gas is not present in the plasma generation zone and its plasma-generating properties are therefore of no importance. However, its nature may have an influence on the transport of the active species near the substrate (hydrodynamics and diffusion) or even on their deexcitation/recombination. These precursors are incorporated into said carrier gas with a partial pressure sufficient to provide, after dissociation into active radicals in the plasma or in the immediate vicinity thereof (the so-called post-discharge plasma zone), a sufficient flux of atoms in the active gas jet impinging on the substrate in order to constitute the film material with the required growth rate. This implies vaporizing the precursor at a high enough temperature, at which temperature the carrier gas will be maintained up to the point of injection into the active gas curtain extracted from the plasma creation zone by coupling with the very high-frequency waves. This temperature has a practical upper limit set by the resistance of the materials of the PECVD module (obviously, it is assumed that the precursor does not decompose prematurely by a simple thermal effect at this maximum temperature).

According to one particular method of implementation, the precursors, which are chosen from the group comprising: gases stored in compressed or liquefied form under a high vapor pressure at room temperature; liquid organometallics having a low vapor pressure; and mixtures thereof. The gaseous precursors are chosen from the group comprising especially silane, methane, acetylene, ethylene and mixtures thereof. The organometallics are chosen from the group comprising precursors of solid materials, namely metal oxides, nitrides and carbides, and mixtures thereof, more particularly organotitanium and organotin compounds, and tetramethylsilane.

Like any atmospheric-pressure plasma-CVD process, the process according to the invention is subject to limitations resulting from the much more frequent interactions between particles in the gas phase. In accordance with the invention, several novel aspects are combined to minimize these effects on the treatment rate and the quality of the films.

Firstly, the main plasma vector gas, generally argon is highly excited in the channel subjacent to the microstrip line. The plasma thus created possesses the characteristics of an atmospheric microwave plasma homogenized by the dynamic flow of the gas. Its electron density at this point is of the order of 10¹¹-10¹¹ cm⁻³ and the temperature of the gas may be from 1000 to 2000 K. The general principle of this method of deposition of an active gas jet extracted from a high-density plasma consists in using this high energy concentration to generate, after a chemical precursor has been injected, a high flux of physical and chemical active species and, at the same time, in transporting the species in the gas flow in the shortest possible time to the surface of the substrate. Thus: 1) the decrease in the number of precursor radicals is limited so as to maintain a high deposition rate; 2) the loss of excited physical species, which help in rearranging the incident atoms and densify the deposited material, is also limited; and 3) the probability of the precursors oligomerizing into coarser clusters of atoms, which are more difficult to optimally accommodate in the film, which would constitute another lack-of-quality factor, is reduced.

Thus, the chemical deposition precursor compound must be introduced into the main flow at not too great a distance downstream of the plasma excitation zone so that the dissociation of the precursor is sufficiently complete to form active radicals. On the other hand, it is not advantageous to overly extend the transit path of these radicals to the surface of the substrate, as they would thus have a higher probability of reacting in the gas phase, either to become inactive and lost for the deposition process, or to undergo oligomerization prejudicial to quality.

However, it is not always judicious to minimize the distance between the plasma generation zone (the channel beneath the microstrip line) and the surface of the substrate to be treated. As mentioned, this enables a maximum amount of nonthermal active species to be provided on the surface of the growing film (for the highest deposition rate and best quality). However, the closer the substrate is placed to the plasma excitation source, the more it is exposed to high temperatures, which may exceed the endurance limit of the material, especially where this is a polymer. In dynamic deposition mode (relative tangential displacement between the PECVD source and the treated substrate), the maximum temperature also depends on the run speed or the scan speed. Thus, a person skilled in the art is capable of adapting this distance to the nature of the support to be treated and to the speed of displacement of the support relative to the plasma source.

As mentioned above, the process of the present invention is carried out using a device as described in the patent application filed on the same day by the Applicant (again described above in the present description) with which a precursor feed unit is associated.

Thus, the invention relates to a plasma-enhanced chemical vapor thin-film deposition device which comprises at least one very high-frequency (>100 MHz) source connected via an impedance matching device to an elongate conductor of small cross section compared with its length (whether of the microstrip line type or hollow, for example cylindrical, conductor line type) fixed to a dielectric support, at least one means for cooling said conductor, at least one plasma gas feed close to the dielectric support on the opposite side on the side supporting the conductor, the plasma being generated beneath the dielectric along the conductor line, and at least one precursor feed injecting precursors into the active gas stream extracted from the plasma creation zone by coupling with the microwaves.

The features of the device described and claimed in the application filed on the same day by the Applicant are included by reference in the description of the device of the present invention.

A gas feed “close to” or “in the vicinity of” the dielectric support is understood to mean an inlet opening typically at less than 15 mm from the support and preferably less than 10 mm from the support.

In the present invention, the term “microstrip line” is understood to mean an electrical conductor element of elongate shape and of small thickness, typically of the order of one millimeter or less than one millimeter. The length and the width of the microstrip line are not arbitrary but are designed so as to optimize the properties for power propagation along the transmission line constituting the microstrip line. As a variant, as already mentioned above, the microstrip line may be replaced with a hollow elongate element, especially of round, rectangular or square cross section, the wall thickness of the hollow tube being sufficient for good mechanical strength and have no effect on the electrical behavior. The microstrip line is not constrained to a particular plane rectilinear geometry, rather it may also adopt a curved shape in the plane or a warped shape in its length direction with concave or convex curvatures.

It should be understood, both in the foregoing and in the following description, that no distinction should be made between conductor, hollow conducting line and microstrip line, and that at no moment can the present invention be restricted to just one of these types of line.

On account of the fact that the high-frequency currents flow while obeying the skin effect and the fact that the latter depends on the frequency and the conductivity of the material constituting the conductor, the practical thickness in which the current flows will be very much less than 0.1 mm. However, because the transported powers are high, of the order of a few hundred watts, and because the conductivity of the metal decreases with increasing temperature, the thickness of the microstrip line will be very much greater than the theoretical thickness defined by the skin effect, and it will be necessary to cool the microstrip line so that it retains its physical integrity. Thus, the microstrip line will have a thickness of the order of one millimeter and be made of a material which is a good electrical and thermal conductor, chosen from those having good mechanical strength, which may be copper alloys such as, for example, brass or, preferably, beryllium copper.

Advantageously, the device according to the invention includes, beneath the channel provided in the dielectric substrate and confining the plasma creation region by coupling with the microwave power, a slot through which the flowing active gas curtain extracted from the plasma creation zone escapes, and the precursor feed means are placed in such a way that the precursors arrive in the slot perpendicular to the active gas stream.

Particularly advantageously, the plasma gas stream is fed in symmetrically via two opposed lateral inlets into the active zone for coupling the microwave power to the plasma. These inlets may open at a variable distance from the surface of the dielectric substrate in order to give the gas stream suitable dynamics in the plasma confinement channel. For example, the inlets may open close to the lower limit of the microwave coupling zone, or even slightly beyond it. In this case, a vortex effect will be created in the plasma channel, which extracts the active species efficiently but prevents an effect in which the plasma is “blown” by the stream, which could be prejudicial to the stability of the latter. The stream is then forced along the perpendicular direction into the injection slot of the active gas “curtain” or jet toward the surface of the substrate. The gas carrying the chemical precursors, providing the atoms making up the material to be deposited, is injected symmetrically and perpendicularly into the active gas stream.

According to one particular embodiment, the precursor feed means are placed in a feed block which is placed beneath the device and can be removed therefrom. It is then possible to have a set of feed blocks of different heights. Thus, by choosing the feed block it is possible to adapt both the distance from the excitation zone where the plasma is excited by coupling the very high-frequency power beneath the microstrip line at the outlet of the jet into the free space, and also the distance between the point of precursor injection and the substrate to be treated, according to the treatment conditions.

Given that the device according to the invention is operated at atmospheric pressure, because of the dynamics of the gas flow impacting the surface, all the incident radicals do not reach said surface directly, in order to be definitively incorporated into the film, and recirculations are established in the vicinity of the surface, which will prolong the residence time of the radicals in the gas phase and promote interactions within said gas phase, prejudicially to the quality of the material deposited on either side of the point of impact of the plasma curtain. It is therefore beneficial to adapt the shape of the plasma injection slot by adding, for example, deflector devices on the treatment head so as to reduce recirculations.

As an illustration, an exemplary embodiment will be described below. Thus, the optimum shape of the microstrip line makes it possible to generate the plasma in the subjacent slot over a length of about 150 mm and a cross section of about 8 mm with an incident power of 300 W used with an efficiency of 97%, which represents a very substantial linear energy density and therefore very substantial density of active species. The device used in a plasma gas in which argon is the very predominant component, may however withstand very much greater power levels, for example 500 to 600 W, thereby improving the deposition rate and the quality of the coating.

The total gas (plasma gas, carrier gas and precursors) flow rate range permitting this operation, about 10 to 100 slm (standard liters per minute), offers a wide range of possibilities for controlling the dynamics of transferring the active species jet coming from the plasma on to the substrate to be treated, so as to optimize the process. Finally, the device is remarkable for the quality of its plasma energy transmission efficiency (impedance matching). Even more than a very low average value for the reflective power (3%), this value is maintained over a very wide range of variation of the operational parameters. The operation of the PECVD module will therefore be particularly robust and insensitive to the variations and fluctuations in the operating conditions imposed by the application (multi-step treatment, idle operation between passes, etc.).

Various devices according to the invention may be juxtaposed, so as in particular to increase the speed at which the substrate runs beneath each of said devices and thus increase the productivity of the process.

The device operated according to the invention will be better understood from the description of the drawings below, in which:

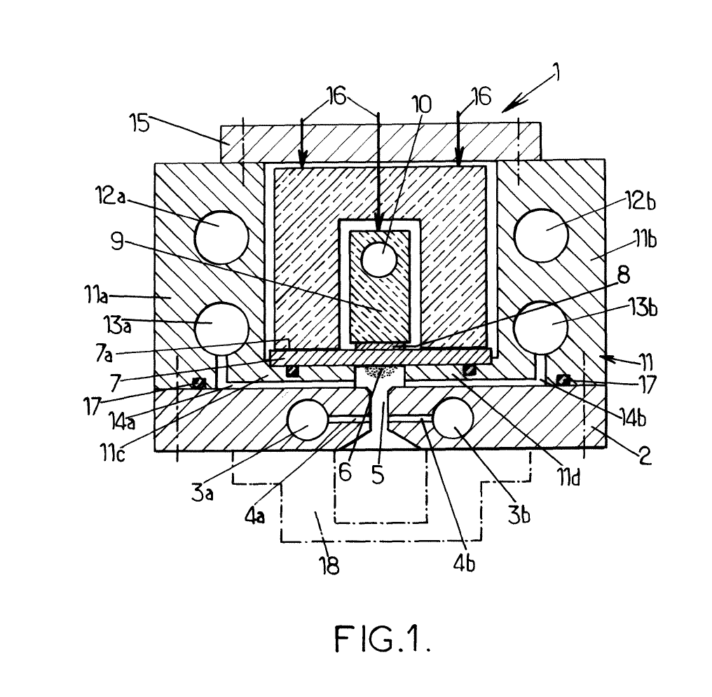

FIG. 1 shows a cross section of a device according to the invention; and

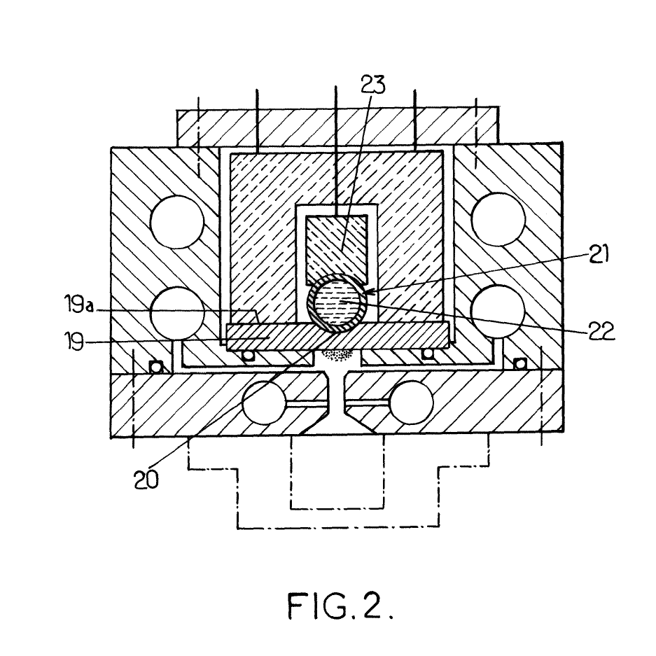

FIG. 2 shows a cross section of an alternative device with a transmission line of cylindrical cross section incorporating internal water circulation.

FIG. 1 shows a device 1 according to the invention, consisting of the following various elements stacked one on top of another:
a base 2 penetrated by two symmetrical longitudinal channels 3a and 3b through which the precursors for depositing solid materials pass, these channels being each connected symmetrically via a precursor delivery slot 4a and 4b to a central outlet slot 5 enabling the active gas stream coming from the plasma 6 to be extracted;
a dielectric 7 in the form of a parallelepipedal plate;
a microstrip line 8 placed centrally on the face 7a of the dielectric 7, consisting of a conducting metal strip connected to the connector (not shown); the width of the microstrip line is greater than that of the slot 5 so that the upper face of the base 2 acts as a partial ground plane;
a ceramic dielectric heat sink 9, having a longitudinal channel 10 through which water circulates, is applied over the entire surface of the microstrip line 8;
a main delivery block 11 having two symmetrical halves 11a and 11b, of parallelepipedal general shape with, in the lower portion, a shoulder 11c, 11d extending toward the center of the device, on the free surface of which shoulders the dielectric bears, the two free ends of these shoulders facing each other with the central slot 5 left free, each of 11a and 11b of the block 11 being penetrated in its upper portion by a longitudinal cylindrical channel 12a and 12b through which cooling water flows and in its lower portion by a longitudinal cylindrical channel 13a and 13b via which the plasma gas arrives, each of the channels 13a and 13b emerging via a slot 14a and 14b in the central slot 5;
a dielectric support block 14 in the form of an upside-down U on top of the dielectric heat sink 10 ensures that the dielectric substrate 7, the lower portion of the delivery block 11 and the base 2 are held together; and
a metal closure plate 15 is fastened to the block 11 and enables a clamping system 16 to be incorporated, which clamping system makes it possible to hold in place the block 11 and the dielectric heat sink 9 on the base 2, on the one hand, and to hold in place the dielectric block 14 pressing the dielectric substrate 7 on the block 11; an O-ring seal 17 located in the lower portion of the block 11 and an O-ring seal located beneath the dielectric 7 ensure that the volume in which the discharge develops is sealed.

The metal plate 15 closes off the block 11 in the upper portion, the whole assembly thus constituting a Faraday cage so as to confine the very high-frequency electromagnetic radiation delivered by the microstrip line so as not to lose energy and not to cause interference (electromagnetic compatibility and operator safety problems) in the environment.

Placed beneath the base 2 is a low-pressure plasma ignition chamber 18. This chamber makes it possible, if necessary, using external pumping means (not shown), to lower the pressure in the zone for coupling the electromagnetic power beneath the microstrip line in order to make ignition easier (ignition being obviously more difficult at atmospheric pressure). This chamber is shown by the dotted lines, as it is moveable and is removed as soon as the plasma has been ignited.

FIG. 2 shows another embodiment of the plasma generator device of the invention that differs from that of FIG. 1 by the fact that the dielectric 7/stripline 8/insulating heat sink 10 has been replaced with a system comprising a dielectric 19 of generally parallelepipedal shape on the surface 19a of which a longitudinal recess has been made that matches the profile of a propagation line element in the form of a hollow conductor tube 21 through which the cooling water 22 circulates, said hollow tube being surmounted by a dielectric retaining block 23.

A device according to the invention may advantageously be placed on a robot arm in such a way that a substrate possibly of large size and of warped shape can be treated without the substrate moving, by scanning the surface of the substrate using the robot arm.

The process of the invention and/or the device of the invention may be used in various applications, especially for coatings providing one or more functionalities of the following types: abrasion resistance, chemical barrier, thermal resistance, corrosion resistance, optical filtering, adhesion primer, UV resistance, etc.

In particular, the invention is very suitable for applying an electrically conducting inorganic film on polymeric automobile body components, particularly fenders, before paint is sprayed electrostatically thereon. This film is the replacement for conducting adhesion primer solutions applied by liquid processing, which require a time-consuming drying operation.

Thus, another subject of the invention is the use of the process as described above for applying an electrically conducting inorganic film on automobile body components, particularly fenders, before the paint is sprayed electrostatically. In this particular use, the material is chosen in particular from the group comprising: tin oxides and indium tin oxide (ITO); titanium nitride TiN and nitrogen-doped titanium oxide; and optionally doped silicon and/or carbon alloys. The corresponding precursors will in particular be tetra-n-butyltin, titaniumisopropoxide, tetramethylsilane and ethylene.

The materials deposited using such precursors meet the functional requirement of the primary coating being able to discharge the electrostatic charges, which requirement is expressed in terms of surface resistivity given in ohms per square (Ω/□) (any square portion of the coating having the same resistance irrespective of the length of each side). Values of the order of 1000Ω/□ seem to be very suitable for the application. Coatings are confined to thin films of reasonable thickness (in relation to the expected treatment time), typically of the order of 1000 nm, this gives the material a resistivity of less than 10⁻³ Ω.m.

1-32. (canceled)

33. An apparatus for forming a chemical vapor deposition plasma, the apparatus comprising:
a) at least one very high-frequency power source adapted to generate electromagnetic radiation of greater than 100 MHz,
b) a microstrip line or hollow-conductor line conductor,
c) an impedance matching device configured to operably connect the very high-frequency power source to the line conductor,
d) a dielectric substrate operably connected to the line conductor on a first dielectric substrate side,
e) a plasma formation zone bounded in part by a second side of the dielectric substrate such that the dielectric substrate is capable of transferring a very high frequency power from the very high-frequency power source to the plasma formation zone,
f) at least one plasma gas feed configured to direct a flow of plasma forming gas into a proximity of the dielectric substrate such that the very high-frequency power is capable of forming a plasma,
g) at least one precursor feed configured to direct one or more chemical vapor deposition precursors, and
h) a system adapted to cool the apparatus during operation.

34. The apparatus of claim 33 further comprising
a) a base having a slot passing through the base and
wherein the precursor feed is configured to direct one or more chemical vapor deposition precursors into the slot in a direction perpendicular to a line from the dielectric substrate through the slot.

35. The apparatus of claim 33 further comprising a partial ground plane facing the second side of the dielectric substrate.

36. The apparatus of claim 35, wherein the partial ground plane is located at a first area of the line conductor comprising the point where the microwaves arrive in the device.

37. The apparatus of claim 36 configured to generate plasma extending with the conductor over a second area of the conductor line, wherein the plasma is capable of functioning as potential reference for guided microwave propagation.

38. A process for plasma enhanced chemical vapor deposition, the process comprising the steps of:
a) forming a very high-frequency electromagnetic radiation of greater than 100 MHz,
b) transmitting the very high-frequency electromagnetic radiation through a line conductor to a plasma gas at atmospheric pressure to form a plasma,
c) combining the atmospheric pressure plasma with one or more precursors to form an activated precursor, and
d) exposing a surface to the activated precursors to form a deposition layer of the activated precursors on the surface.

39. The process of claim 38, wherein the plasma gas comprises argon gas.

40. The process of claim 39, wherein the plasma gas further comprises 0.1 to 5 percent nitrogen.

41. The process of claim 39, wherein the precursor comprises a gas stored in compressed or liquefied form under a high vapor pressure at room temperature and/or a liquid organometallic having a low vapor pressure.

42. The process of claim 41 wherein the gas stored in compressed or liquefied form under a high vapor pressure at room temperature comprises silane, methane, acetylene and/or ethylene.

43. The process of claim 41 wherein the liquid comprises titanium, tin, zinc and/or silicon.

44. The process of claim 39 wherein the very high-frequency power source adapted to generate electromagnetic radiation of 434 MHz.

45. The process of claim 39 wherein the plasma gas is delivered to a plasma formation zone at a flow rate of 10 to 100 standard liters per minute.

46. The process of claim 39, wherein the surface is an automobile body component and the precursors are selected to deposit an electrically conducting inorganic film thereon.

47. The process of claim 46 wherein a) the inorganic film comprises tin oxides, indium tin oxide, titanium nitride, nitrogen-doped tin oxide, doped silicon alloys and/or doped carbon alloys, and b) the precursors comprise tetra-n-butyltin, titanium isopropoxide, tetramethylsilane and/or ethylene.
